(19) United States
(12) Patent Application Publication
(10) Pub. No.: US 2024/0203956 A1
(43) Pub. Date: Jun. 20, 2024

(54) LIGHT-EMITTING DEVICE, LIGHT-EMITTING APPARATUS, AND PLANT LIGHTING APPARATUS

(71) Applicant: TIANJIN SANAN OPTOELECTRONICS CO., LTD., Tianjin (CN)

(72) Inventors: Cheng MENG, Tianjin (CN); Dongmei CAO, Tianjin (CN); Huan-Shao KUO, Tianjin (CN); Yu-Ren PENG, Tianjin (CN); Duxiang WANG, Tianjin (CN)

(21) Appl. No.: 18/591,488

(22) Filed: Feb. 29, 2024

Related U.S. Application Data
(63) Continuation-in-part of application No. PCT/CN2021/143830, filed on Dec. 31, 2021.

(51) Int. Cl. H01L 25/075; H01L 33/42; H01L 33/46

(52) U.S. Cl. CPC H01L 25/0753; H01L 33/42; H01L 33/46

(57) ABSTRACT

A light-emitting device includes a semiconductor epitaxial structure, a reflection layer, and a light-transmissive dielectric structure. The semiconductor epitaxial structure has a first surface and a second surface, and includes a first semiconductor layer, an active layer, and a second semiconductor layer. The first surface is a light-exiting surface. The reflection layer is disposed on the semiconductor epitaxial structure away from the light-exiting surface, and is adapted for reflecting light emitted by the active layer. The light-transmissive dielectric structure is disposed between the reflection layer and the semiconductor epitaxial structure, and includes a first sublayer, a second sublayer, and a third sublayer. A light-emitting apparatus and a plant lighting apparatus are also provided.

### CROSS-REFERENCE TO RELATED APPLICATION

This application is a continuation-in-part (CIP) of International Application No. PCT/CN2021/143830, filed on Dec. 31, 2021, the entire disclosure of which is incorporated by reference herein.

### FIELD

The disclosure relates to a semiconductor optoelectronics device, and more particularly to a light-emitting device, a light-emitting apparatus, and a plant lighting apparatus.

### BACKGROUND

Light-emitting devices (LEDs) have advantages of high luminous brightness, high efficiency, small size, long lifespan, etc., and are considered to be one of the light sources having the most potential. In recent years, LEDs have been widely used in daily life, such as illumination, signal display, backlight, vehicle lamps, and large screen display. These applications ask for a higher level of luminous brightness and light-emitting efficiency of the LEDs.

A conventional light-emitting device may be a horizontal type light-emitting device or a vertical type light-emitting device. The vertical type light-emitting device is manufactured by transferring a semiconductor epitaxial structure from a growth substrate onto a supporting substrate, which may be made of silicon, silicon carbide, or metal, and then removing the growth substrate. Compared to the horizontal type light-emitting device, technical problems such as light absorption, current crowding, or poor heat dissipation caused by the growth substrate may thereby be effectively mitigated. A bonding process, such as metal-metal bonding under high temperature and high pressure, is conducted to transfer the semiconductor epitaxial structure. That is to say, a metal bonding layer is formed between a side of the semiconductor epitaxial structure and the supporting substrate. Another side of the semiconductor epitaxial structure is a light exiting side (i.e., a light-exiting surface). An electrode is disposed on the light exiting side for injection or outflow of current, and the supporting substrate is for injection or outflow of the current, thereby manufacturing a light-emitting device having the current flowing vertically through the semiconductor epitaxial structure.

To improve light-emitting efficiency, a metal reflection layer and a light-transmissive dielectric layer are usually provided on one side of the metal bonding layer, and cooperatively form an omni directional reflector (ODR) which reflects light from the metal bonding layer to the light-exiting surface so as to improve the light-emitting efficiency.

Currently, the ODR totally reflects the light that has an incident angle greater than a critical angle back to the semiconductor epitaxial structure and then emits the light from the light-exiting surface. The light that has an incident angle smaller than the critical angle may be reflected back and forth within the semiconductor epitaxial structure, and then be emitted from or absorbed by the semiconductor epitaxial structure. To improve light extraction efficiency of the light-emitting device, the fewer the times that the light is reflected within the semiconductor epitaxial structure, the greater the chance that the light may be extracted, and the smaller the chance that the light is absorbed.

### SUMMARY

Therefore, an object of the disclosure is to provide a light-emitting device that can alleviate at least one of the drawbacks of the prior art.

According to the disclosure, the light-emitting device includes a semiconductor epitaxial structure, a reflection layer, and a light-transmissive dielectric structure.

The semiconductor epitaxial structure has a first surface and a second surface opposite to the first surface, and includes a first semiconductor layer, an active layer, and a second semiconductor layer sequentially disposed in a stacking direction from the first surface to the second surface. The first surface is a light-exiting surface.

The reflection layer is disposed on the semiconductor epitaxial structure away from the light-exiting surface, and is adapted for reflecting light emitted by the active layer.

The light-transmissive dielectric structure is disposed between the reflection layer and the semiconductor epitaxial structure. The light-transmissive dielectric structure includes a first sublayer made of a first material, a second sublayer made of a second material, and a third sublayer made of a third material that are sequentially disposed in the stacking direction. The first sublayer has a first refractive index (n1), the second sublayer has a second refractive index (n2), and the third sublayer has a third refractive index (n3), where n2>n1, n2>n3.

A light-emitting apparatus and a plant lighting apparatus are also provided.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a first embodiment of a light-emitting device according to the disclosure.

FIG. 2 is a schematic cross-sectional view illustrating a second embodiment of the light-emitting device according to the disclosure.

FIG. 3 is a schematic cross-sectional view illustrating a third embodiment of the light-emitting device according to the disclosure.

FIG. 4 is a schematic cross-sectional view illustrating a fourth embodiment of the light-emitting device according to the disclosure.

FIG. 5 is a schematic cross-sectional view illustrating a fifth embodiment of the light-emitting device according to the disclosure.

FIG. 6 is a schematic cross-sectional view illustrating a sixth embodiment of the light-emitting device according to the disclosure.

FIG. 7 is a schematic cross-sectional view illustrating a seventh embodiment of the light-emitting device according to the disclosure.

FIG. 8 is a schematic cross-sectional view illustrating an eighth embodiment of the light-emitting device according to the disclosure.

FIG. 9 is a schematic cross-sectional view illustrating a ninth embodiment of the light-emitting device according to the disclosure.

FIGS. 10 to 13 are schematic diagrams illustrating a method for manufacturing the sixth embodiment of the light-emitting device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

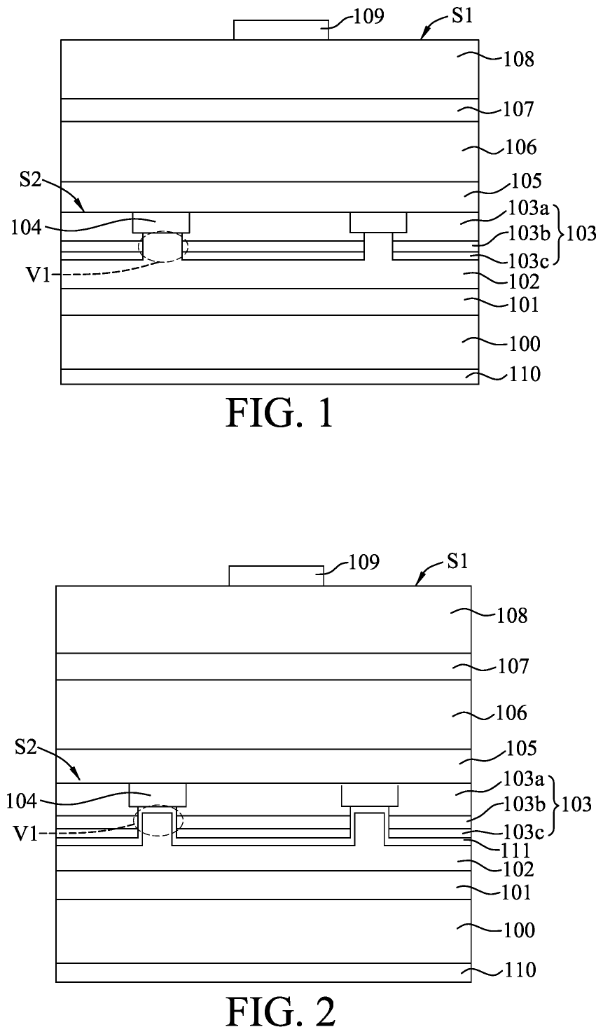

Referring to FIG. 1, a first embodiment of a light-emitting device according to the disclosure is provided and includes a supporting substrate 100, a metal bonding layer 101, a reflection layer 102, a light-transmissive dielectric structure 103 which includes a first sublayer 103a, a second sublayer 103b and a third sublayer 103c, an ohmic contact layer 104, a current spreading layer 105, a second semiconductor layer 106, an active layer 107, a first semiconductor layer 108, a first electrode 109, and a second electrode 110.

In this embodiment, the light-emitting device includes a semiconductor epitaxial structure, which is obtained by metal-organic chemical vapor deposition (MOCVD) or other growth methods and may contain a semiconductor material that generates light, such as ultra-violet light, blue light, green light, yellow light, red light, and infrared light. The semiconductor material of the semiconductor epitaxial structure may be a material that generates light with a wavelength ranging from 200 nm to 950 nm, such as a nitride material. In some embodiments, the semiconductor epitaxial structure may be a GaN-based semiconductor epitaxial structure which may be doped with elements such as aluminum and indium, and which generates light having a wavelength ranging from 200 nm to 550 nm. In other embodiments, the semiconductor epitaxial structure is an AlGaInP-based semiconductor epitaxial structure or an AlGaAs-based semiconductor epitaxial structure that generates a light having a wavelength ranging from 550 nm to 950 nm.

The semiconductor epitaxial stack has a first surface (S1) and a second surface (S2) opposite to the first surface (S1), and includes the first semiconductor layer 108, the active layer 107, and the second semiconductor layer 106 sequentially disposed in a stacking direction from the first surface (S1) to the second surface (S2). The first surface (S1) is a light-exiting surface. The first semiconductor layer 108 and the second semiconductor layer 106 may be respectively an n-type doped semiconductor layer or a p-type doped semiconductor layer to provide electrons and holes, respectively. The n-type semiconductor layer may be doped with an n-type dopant such as Si, Ge, or Sn, and the p-type semiconductor layer may be doped with a p-type dopant such as Mg, Zn, Ca, Sr, or Ba. Each of the first semiconductor layer 108, the active layer 107, and the second semiconductor layer 106 may be made of a material such as AlGaInN, GaN, AlGaN, AlInP, AlGaInP, GaAs or AlGaAs. The active layer 107 is a region for the electrons and the holes to recombine. The active layer 107 may be made of various materials depending on a desired wavelength of light to be emitted by the active layer 107, and may have a single quantum well structure or a multiple quantum well structure. By adjusting a ratio of elements in the semiconductor material of the active layer 107, the active layer 107 may emit light with a desired wavelength. In this embodiment, the semiconductor epitaxial structure is made of an AlGaInP-based material or an AlGaAs-based material, and the active layer 107 generates a light having a wavelength ranging from 550 nm to 950 nm.

To improve current spreading of the light-emitting device, the semiconductor epitaxial structure further includes the current spreading layer 105 disposed on the second semiconductor layer 106 away from the first surface (S1). A material of the current spreading layer 105 may be GaP or GaAs. In this embodiment, the current spreading layer 105 is made of GaP, and has a thickness ranging from 0.02 μm to 1.5 μm. In certain embodiments, the thickness of the current spreading layer 105 ranges from 0.02 μm to 0.4 μm. By thinning the thickness of the current spreading layer 105, light absorption by the current spreading layer 105 may be reduced. The current spreading layer 105 may have a doping concentration ranging from 5E17/cm³ to 5E18/cm³.

The semiconductor epitaxial structure is disposed on the supporting substrate 100. The supporting substrate 100 is a conductive substrate, such as a silicon substrate, a silicon carbide substrate, or a metal substrate. The metal substrate may be a copper substrate, a tungsten substrate, a copper tungsten substrate, a molybdenum substrate, etc. The supporting substrate 100 may have a thickness no smaller than 50 μm so as to have sufficient mechanical strength to support the semiconductor epitaxial structure. Furthermore, in other embodiments, in order to facilitate mechanical processing of the supporting substrate 100 after bonding the semiconductor epitaxial structure to the supporting substrate 100, the thickness of the supporting substrate 100 is no greater than 300 μm. In this embodiment, the supporting substrate 100 is a silicon substrate.

The metal bonding layer 101 serves to bond a surface of the semiconductor epitaxial structure away from the light-exiting surface to the supporting substrate 100. The metal bonding layer 101 may be made of a metallic material, such as gold, tin, titanium, tungsten, nickel, platinum, indium, or combinations thereof, and may have a single-layered structure or a multilayered structure. In this embodiment, the metal bonding layer 101 is made of a gold-indium material.

The reflection layer 102 is disposed on the semiconductor epitaxial structure away from the light-exiting surface (i.e., on the metal bonding layer 101 and closer to the semiconductor epitaxial structure than the metal bonding layer 101), and is adapted for reflecting light emitted by the active layer 107 outwardly. In some embodiments, the reflection layer 102 is a metal layer, which is made of Ag, Ni, Al, Rh, Pd, Ir, Ru, Mg, Ti, Cr, Zn, Pt, Au, Hf or combinations thereof. The reflection layer 102 has a reflectivity no smaller than 70%. In this embodiment, the reflection layer 102 is made of Au or Ag. The reflection layer 102 may reflect light radiated by the semiconductor epitaxial structure towards the supporting substrate 100 back to the semiconductor epitaxial structure, and then emit the light outwardly from the light-exiting surface, i.e., the first surface (S1). In this embodiment, the first surface (S1), i.e., the light-exiting surface, of the light-emitting device is a surface of the first semiconductor layer 108 away from the active layer 107.

The light-transmissive dielectric structure 103 is disposed between the reflection layer 102 and the semiconductor epitaxial structure. The light-transmissive dielectric structure 103 has different refractive indices at different positions along the stacking direction of the semiconductor epitaxial structure. The light-transmissive dielectric structure 103 has different refractive indices at least at two different positions along the stacking direction of the semiconductor epitaxial structure. The reflection layer 102 and the light-transmissive dielectric structure 103 form a total-reflection structure that reflects light from the semiconductor epitaxial structure toward the light-exiting surface, thereby increasing light-exiting efficiency. To further improve the light-exiting efficiency of the light-emitting device, in this embodiment, the light-transmissive dielectric structure 103 includes the first sublayer 103a made of a first material, the second sublayer 103b made of a second material, and the third sublayer 103c made of a third material that are sequentially disposed in the stacking direction. The first sublayer 103a has a first refractive index (n₁), the second sublayer 103b has a second refractive index (n₂), and the third sublayer 103c has a third refractive index (n₃), where n₂>n₁ and n₂>n₃.

In certain embodiments, the second material is different from the first material and the third material, and the first material is the same as or different from the third material.

The second semiconductor layer 106 or the current spreading layer 105 has a refractive index (n₀). In some embodiments, the first refractive index (n₁) of the first sublayer 103a is smaller than the refractive index (n₀) of the second semiconductor layer 106 or the current spreading layer 105. That is to say, n₀>n₁. The first material includes MgF₂ or SiOₓ. The second material includes TiO₂ or SiNₓ. The third material includes MgF₂ or SiOₓ. The first sublayer 103a has a thickness of kλ/4n₁, the second sublayer 103b has a thickness of kλ/4n₂, and the third sublayer 103c has a thickness of kλ/4n₃. λ is a wavelength of the light emitted by the active layer 107, and k is an odd number. In this embodiment, the light-transmissive dielectric structure 103 is made of SiO₂/SiNₓ/SiO₂.

The light-transmissive dielectric structure 103 has a through hole (V1). The reflection layer 102 fills the through hole (V1) and covers a top surface of the light-transmissive dielectric structure 103 away from the semiconductor epitaxial structure. In this embodiment, the light-transmissive dielectric structure 103 has a plurality of the through holes (V1). The light-transmissive dielectric structure 103 and the reflection layer 102 form the total-reflection structure, where total reflection occurs at an interface between the current spreading layer 105 and the first sublayer 103a, and an interface between the second sublayer 103b and the third sublayer 103c to reflect light with a large incident angle. Light with a small incident angle is refracted between the light-transmissive dielectric structure 103 and the reflection layer 102 and then undergoes specular reflection, so as to emit light from the active layer 107 to the light-exiting surface for the light to be emitted outwardly therefrom.

In this embodiment, the light-emitting device further includes the ohmic contact layer 104 that is disposed between the semiconductor epitaxial structure and the reflection layer 102. The ohmic contact layer 104 is disposed on the current spreading layer 105 away from the semiconductor epitaxial structure, and forms an ohmic contact with the current spreading layer 105. The ohmic contact layer 104 has a patterned structure, which may be a regular pattern or an irregular pattern for reducing light absorption of the ohmic contact layer 104. The ohmic contact layer 104 is a transparent conductive layer or a conductive metallic layer. The ohmic contact layer 104 is made of ITO, IZO, gold-zinc, gold-germanium, nickel-gold, gold-germanium-nickel, gold-beryllium, or combinations thereof. In this embodiment, the ohmic contact layer 104 is made of ITO. The light-transmissive dielectric structure 103 covers a part of a top surface of the ohmic contact layer 104 away from the semiconductor epitaxial structure and a side surface of the ohmic contact layer 104, as shown in FIG. 1. In this embodiment, the ohmic contact layer 104 corresponds in position to the through hole (V1).

The first electrode 109 is disposed on the light-exiting surface (i.e., the first surface (S1)) of the semiconductor epitaxial structure. In some embodiments, the first electrode 109 includes a pad electrode and an extension electrode (not shown), where the pad electrode is used for external wiring while packaging. The pad electrode may be designed to have different shapes, such as a cylindrical shape, a block shape or other polygonal shapes, depending on actual requirements. The extension electrode may be formed to have a predetermined pattern, and may have various shapes such as a strip.

The light-emitting device further includes the second electrode 110. In this embodiment, the second electrode 110 is disposed on and completely covers a surface of the supporting substrate 100 opposite to the semiconductor epitaxial structure. In the present embodiment, the supporting substrate 100 is a conductive supporting substrate, and the first electrode 109 and the second electrode 110 are respectively disposed on opposite sides of the supporting substrate 100 so as to achieve vertical flow of current through the semiconductor epitaxial structure and provide a uniform current density. In certain embodiments, each of the first electrode 109 and the second electrode 110 is made of a metallic material.

Optical reflectivity tests on different films/layers were conducted using TFCalc35, Software for Optical Thin Film. In the tests, the effect of different composition(s) of a light-transmissive dielectric structure on reflectivity was assessed. Sample 1 had a light-transmissive dielectric structure made of a SiO₂ monolayer, Sample 2 had a light-transmissive dielectric structure made of SiO₂/SiNₓ, Sample 3 had the light-transmissive dielectric structure of this embodiment made of SiO₂/SiNₓ/SiO₂, and Sample 4 had a light-transmissive dielectric structure made of SiO₂/SiNₓ/SiO₂/SiNₓ. An optical reflectivity analysis was performed on the abovementioned four samples, and the result shows that Sample 3 has a strongest reflectivity at a wavelength of 650 nm and 670 nm. The reflectivity of Sample 3 is higher than Sample 1 by 1.1%, reflectivity of Sample 4 is higher than Sample 1 by 0.5%, and reflectivity of Sample 2 is lower than Sample 1 by 2%.

To improve adhesion between the light-transmissive dielectric structure 103 and the reflection layer 102, a second embodiment of the light-emitting device not only has the structure of the first embodiment but also includes an adhesive layer 111 disposed on the light-transmissive dielectric structure 103 away from the semiconductor epitaxial structure (i.e., between the light-transmissive dielectric structure 103 and the reflection layer 102), as shown in FIG. 2. The adhesive layer 111 is a made of a light-transmissive material, such as IZO or ITO. In other embodiments, when the reflection layer 102 is made of gold or silver, the adhesive layer 111 is made of a material that provides good adhesion between the light-transmissive dielectric structure 103 and the gold or silver reflection layer 102.

The adhesive layer 111 has a thickness no smaller than 2 nm. In some embodiments, the thickness of the adhesive layer 11 is no smaller than 5 nm so as to provide better adhesion. In certain embodiments, the adhesive layer 111 is a continuous layer. In other embodiments, the adhesive layer 111 may be a discrete layer.

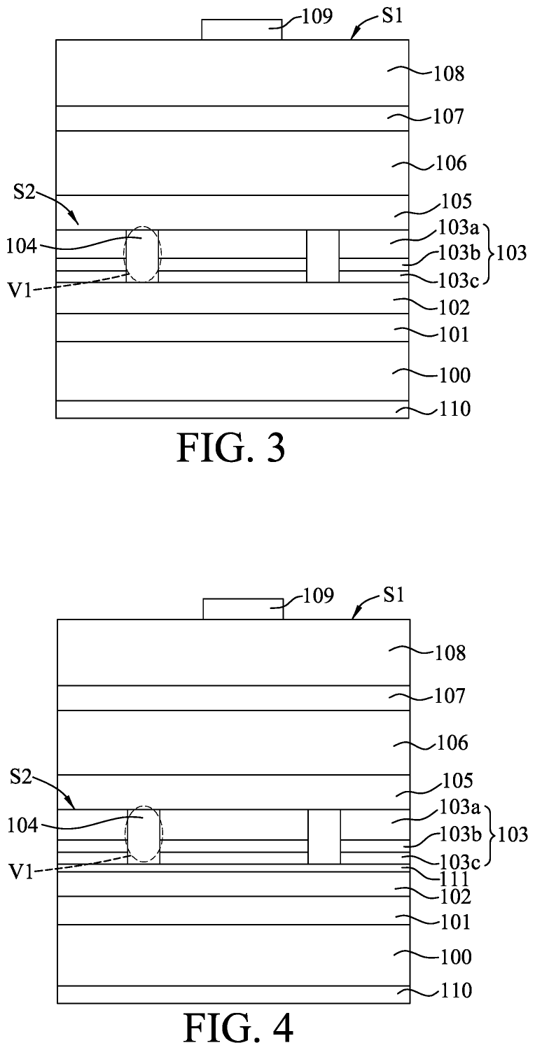

FIG. 3 is a schematic cross-sectional view illustrating a third embodiment of the light-emitting device which has a structure similar to that of the first embodiment. Referring to FIG. 3, the light-transmissive dielectric structure 103 has a plurality of the through holes (V1), and the ohmic contact layer 104 is disposed in at least one of the through holes (V1) of the light-transmissive dielectric structure (103), thereby forming an ohmic contact with the current spreading layer 105. The current passes uniformly from the metal bonding layer 101, the reflection layer 102, and the ohmic contact layer 104 through the at least one of the through holes (V1) to the semiconductor epitaxial structure. That is to say, the ohmic contact layer 104 does not completely cover a surface of the current spreading layer 105 away from the semiconductor epitaxial structure. In this embodiment, the ohmic contact layer 104 is disposed in the plurality of the through holes (V1). The ohmic contact layer 104 is a transparent conductive layer or a conductive metallic layer, and may be made of ITO, IZO, gold-zinc, gold-germanium, nickel-gold, gold-germanium-nickel, gold-beryllium, or combinations thereof, and may have a single-layered structure or a multilayered structure. In this embodiment, the ohmic contact layer 104 is made of gold-zinc.

In some embodiments, as shown in FIG. 3, a surface of the ohmic contact layer 104 away from the semiconductor epitaxial structure and a surface of the light-transmissive dielectric structure 103 away from the semiconductor epitaxial structure are substantially flush with each other, which may ensure evenness of the reflection layer 102 that is subsequently formed, thereby increasing the reflectivity of the reflection layer 102 and the light-exiting efficiency of the light-emitting device.

In certain embodiments, the ohmic contact layer 104 is disposed in at least one of the through holes (V1) of the light-transmissive dielectric structure 103 and extends outside the at least one of the through holes (V1).

The reflection layer 102 is disposed on the light-transmissive dielectric structure 103 and the ohmic contact layer 104 away from the semiconductor epitaxial structure. The reflection layer 102 and the light-transmissive dielectric structure 103 form the total-reflection structure, which reflects the light from the active layer 107 to the metal bonding layer 101 back to the light-exiting surface, thereby increasing the light-exiting efficiency and luminous brightness of the light-emitting device.

To improve the adhesion between the light-transmissive dielectric structure 103 and the reflection layer 102, as shown in FIG. 4, a fourth embodiment of the light-emitting device not only has the structure of the third embodiment but also includes the adhesive layer 111 disposed on the light-transmissive dielectric structure 103 away from the semiconductor epitaxial structure. The adhesive layer 111 is made of a light-transmissive material such as IZO or ITO. In other embodiments, when the reflection layer 102 is made of gold or silver, the adhesive layer 111 is made of a material that provides good adhesion between the light-transmissive dielectric structure 103 and the gold or silver reflection layer 102.

The adhesive layer 111 has a thickness no smaller than 2 nm. In some embodiments, the thickness of the adhesive layer 11 is no smaller than 5 nm so as to provide better adhesion. In certain embodiments, the adhesive layer 111 is a continuous layer. In other embodiments, the adhesive layer 111 may be a discrete layer.

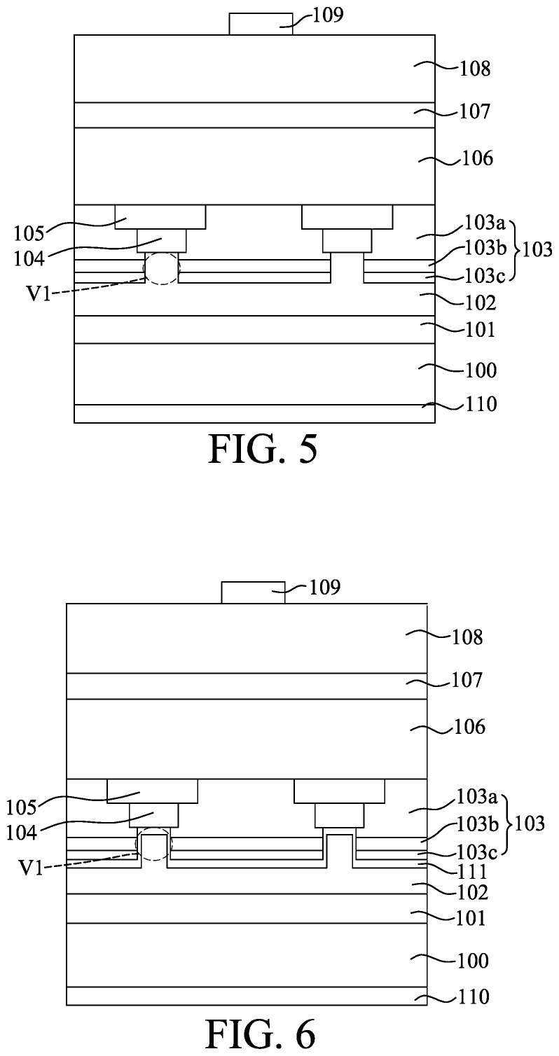

FIG. 5 is a schematic cross-sectional view illustrating a fifth embodiment of the light-emitting device according to the disclosure which has a structure similar to that of the first embodiment. As shown in FIG. 5, in this embodiment, the current spreading layer 105 has a recess region and a non-recess region. The non-recess region of the current spreading layer 105 has a thickness greater than a thickness of the recess region of the current spreading layer 105. The current spreading layer 105 may include a plurality of the non-recess regions which are independent from each other; the recess region may surround the non-recess regions. A surface of each of the non-recess regions which contacts the ohmic contact layer 104 has a shape, and the shape may be circular, semicircular, triangular, pentagonal, hexagonal, etc. Alternatively, the current spreading layer 105 may include a plurality of the recess regions which are separated from each other; the non-recess region may surround the recess regions. Each of the recess regions has a cross section away from the light-transmissive dielectric layer 103 has a shape, and the shape may be circular, semicircular, triangular, pentagonal, hexagonal, etc.

Referring to FIG. 5, the recess region(s) may penetrate the current spreading layer 105, which means part(s) of the current spreading layer 105 as shown in the first embodiment is(are) removed along the stacking direction. In other embodiments, the recess region(s) may not completely penetrate the current spreading layer 105, i.e., the recess region of the current spreading layer 105 is thinned along the stacking direction. Thinning or removal of the part(s) of the current spreading layer 105 may be implemented by a conventional process such as dry etching. In some embodiments, the recess region of the current spreading layer 105 does not penetrate the current spreading layer 105, and the thickness of the recess region is greater than 0 and not greater than the thickness of the non-recess region. The recess region of the current spreading layer 105 may control flowing direction of current and reduce light absorption of the current spreading layer 105, thereby enhancing the luminous brightness of the light-emitting device.

Referring to FIG. 5, the light-transmissive dielectric layer 103 is disposed between the current spreading layer 105 and the reflection layer 102 and fills the recess region of the current spreading layer 105. The reflection layer 102 is disposed on the non-recess region of the current spreading layer 105 and on the light-transmissive dielectric layer 103 away from the semiconductor epitaxial structure. The ohmic contact layer 104 is disposed between the reflection layer 102 and the non-recess regions of the current spreading layer 105.

The ohmic contact layer 104 has the patterned structure to thereby reduce the light absorption of the ohmic contact layer 104. The ohmic contact layer 104 is a transparent conductive layer or a conductive metallic layer, and is made of gold-zinc, gold-germanium, nickel-gold, gold-germanium-nickel, gold-beryllium, or combinations thereof. In some embodiments, the ohmic contact layer 104 is made of ITO or IZO. The ohmic contact layer 104 may have a single-layered structure or a multilayered structure. The light-transmissive dielectric layer 103 covers a part of a top surface of the ohmic contact layer 104 away from the semiconductor epitaxial structure and a side surface of the ohmic contact layer 104.

To improve the adhesion between the light-transmissive dielectric structure 103 and the reflection layer 102, as shown in FIG. 6, a sixth embodiment of the light-emitting device not only has the structure of the fifth embodiment but also includes the adhesive layer 111 disposed on the light-transmissive dielectric structure 103 away from the semiconductor epitaxial structure (i.e., between the light-transmissive dielectric structure 103 and the reflection layer 102). The adhesive layer 111 is a made of light-transmissive material, specifically such as IZO or ITO. In other embodiments, when the reflection layer 102 is made of gold or silver, the adhesive layer 111 is made of a material that provides good adhesion between the light-transmissive dielectric structure 103 and the reflection layer 102.

The adhesive layer 111 has a thickness no smaller than 5 nm, e.g., ranging from 5 nm to 50 nm so as to provide better adhesion. In certain embodiments, the adhesive layer 111 is a continuous layer. In other embodiments, the adhesive layer 111 may be a discrete layer.

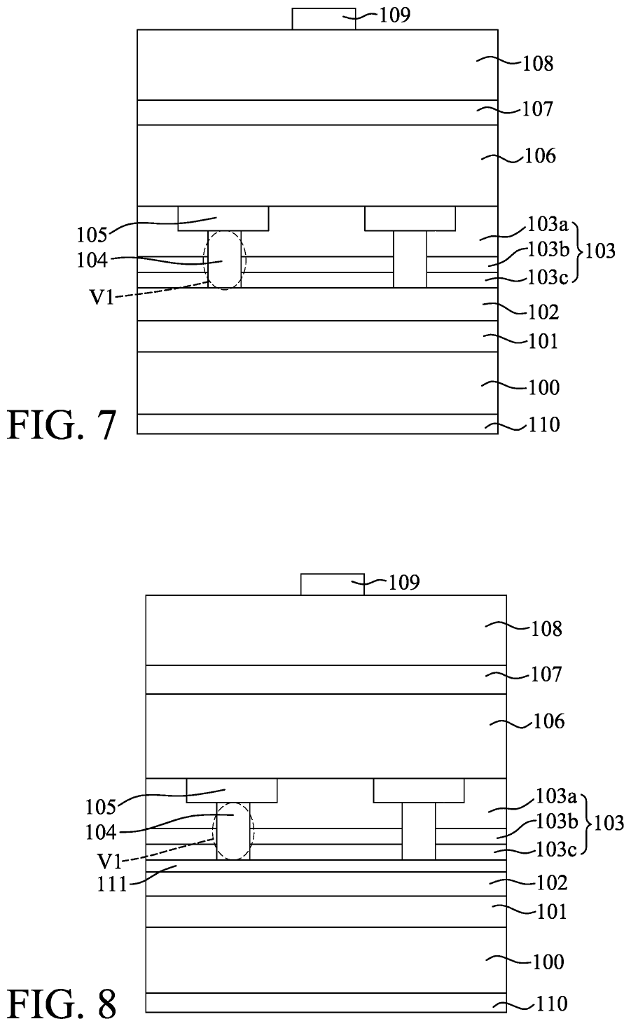

FIG. 7 is a schematic cross-sectional view illustrating a seventh embodiment of the light-emitting device. Similar to the light-emitting device as shown in FIG. 5, in this embodiment, the current spreading layer 105 has the recess region and the non-recess region. The thickness of the non-recess region of the current spreading layer 105 is greater than the thickness of the recess region of the current spreading layer 105, and the light-transmissive dielectric layer 103 is disposed between the current spreading layer 105 and the reflection layer 102 and fills the recess region. The through holes (V1) of the light-transmissive dielectric structure 103 face the non-recess region of the current spreading layer 105. The ohmic contact layer 104 is disposed in at least one of the through holes (V1) of the light-transmissive dielectric structure 103, thereby forming an ohmic contact with the current spreading layer 105. The current passes uniformly from the metal bonding layer 101, the reflection layer 102, and the ohmic contact layer 104 through the at least one of the through holes (V1) to the semiconductor epitaxial structure. The ohmic contact layer 104 does not completely cover the surface of the current spreading layer 105 away from the semiconductor epitaxial structure. The ohmic contact layer 104 is a transparent conductive layer or a conductive metallic layer, is made of ITO, IZO, gold-zinc, gold-germanium, nickel-gold, gold-germanium-nickel, gold-beryllium, or combinations thereof, and may have a single-layered structure or a multilayered structure. In this embodiment, the ohmic contact layer 104 is made of gold-zinc.

In some embodiments, as shown in FIG. 7, the surface of the ohmic contact layer 104 away from the semiconductor epitaxial structure and the surface of the light-transmissive dielectric structure 103 away from the semiconductor epitaxial structure are substantially flush with each other, which may ensure evenness of the reflection layer 102 that is subsequently formed, thereby increasing the reflectivity of the reflection layer 102 and the light-exiting efficiency of the light-emitting device.

In certain embodiments, the ohmic contact layer 104 is disposed in at least one of the through holes (V1) of the light-transmissive dielectric structure and extends outside the at least one of the through hole (V1).

The reflection layer 102 is disposed on the light-transmissive dielectric structure 103 and the ohmic contact layer 104 away from the semiconductor epitaxial structure. The reflection layer 102 and the light-transmissive dielectric structure 103 form the total-reflection structure, which reflects light from the active layer 107 to the metal bonding layer 101 back to the light-exiting surface, thereby increasing the light-exiting efficiency and the luminous brightness of the light-emitting device.

To improve the adhesion between the light-transmissive dielectric structure 103 and the reflection layer 102, as shown in FIG. 8, an eighth embodiment of the light-emitting device not only has the structure of the fifth embodiment but also includes the adhesive layer 111 disposed on the light-transmissive dielectric structure 103 away from the semiconductor epitaxial structure. The adhesive layer 111 is disposed between the light-transmissive dielectric structure 103 and the reflection layer 102, and is made of a light-transmissive material such as IZO or ITO. In other embodiments, when the reflection layer 102 is made of gold or silver, the adhesive layer 111 is made of a material that provides good adhesion between the light-transmissive dielectric structure 103 and the reflection layer 102.

The adhesive layer 111 has a thickness no smaller than 5 nm, e.g., ranging from 5 nm to 50 nm so as to provide better adhesion. In certain embodiments, the adhesive layer 111 is a continuous layer. In other embodiments, the adhesive layer 111 may be a discrete layer.

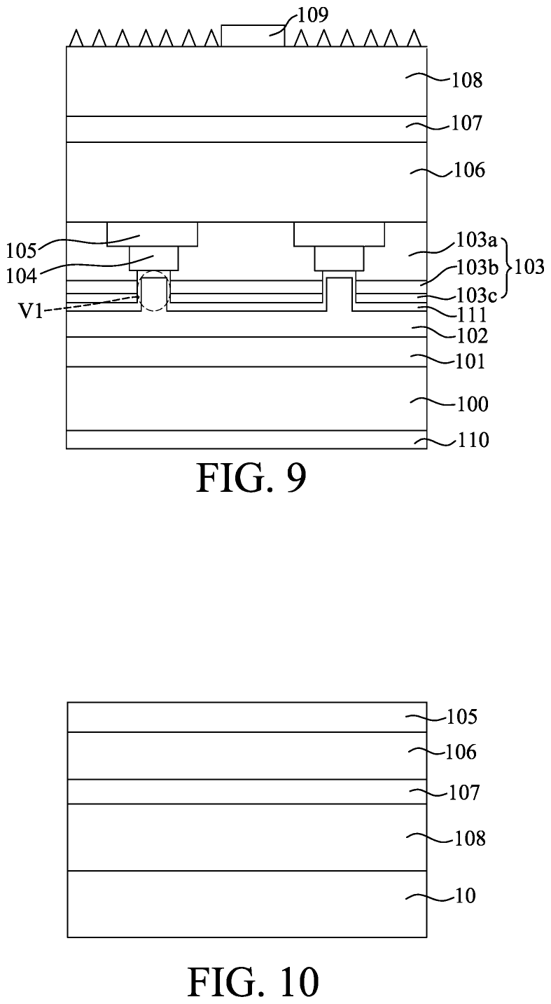

To further improve the luminous efficiency of the light emitted from the active layer 107 and exiting from the light-exiting surface, as shown in FIG. 9, a ninth embodiment not only has the structure of the sixth embodiment but also has a roughened structure on the first surface (S1) of the semiconductor epitaxial structure, but not limited to this embodiment.

The following is a detailed description of a manufacturing method of the sixth embodiment of the light-emitting device.

As shown in FIG. 10, the semiconductor epitaxial structure is provided and includes the first semiconductor layer 108, the active layer 107, the second semiconductor layer 106, and the current spreading layer 105.

Specifically, a growth substrate 10 is first provided and may be made of GaAs. Through an epitaxial process, such as MOCVD, the semiconductor epitaxial structure which includes the first semiconductor layer 108, the active layer 107, the second semiconductor layer 106 and the current spreading layer 105 is grown on the growth substrate 10. When the first semiconductor layer 108 is an n-type doped semiconductor layer, the second semiconductor layer 106 is a p-type doped semiconductor layer having an electrical property different from that of the first semiconductor layer 108. Alternately, when the first semiconductor layer 108 is a p-type doped semiconductor layer, the second semiconductor layer 106 is an n-type doped semiconductor layer. The active layer 107 may be an intrinsic semiconductor layer, a p-type doped semiconductor layer or an n-type doped semiconductor layer. When a current is applied to the semiconductor epitaxial structure, the active layer 107 is activated to emit light. In this embodiment, each of the second semiconductor layer 106 and the current spreading layer 105 is a p-type doped semiconductor layer. The semiconductor epitaxial structure is an AlGaInP-based semiconductor epitaxial structure or a GaAs-based semiconductor epitaxial structure, and the active layer 107 radiates red light or infrared light.

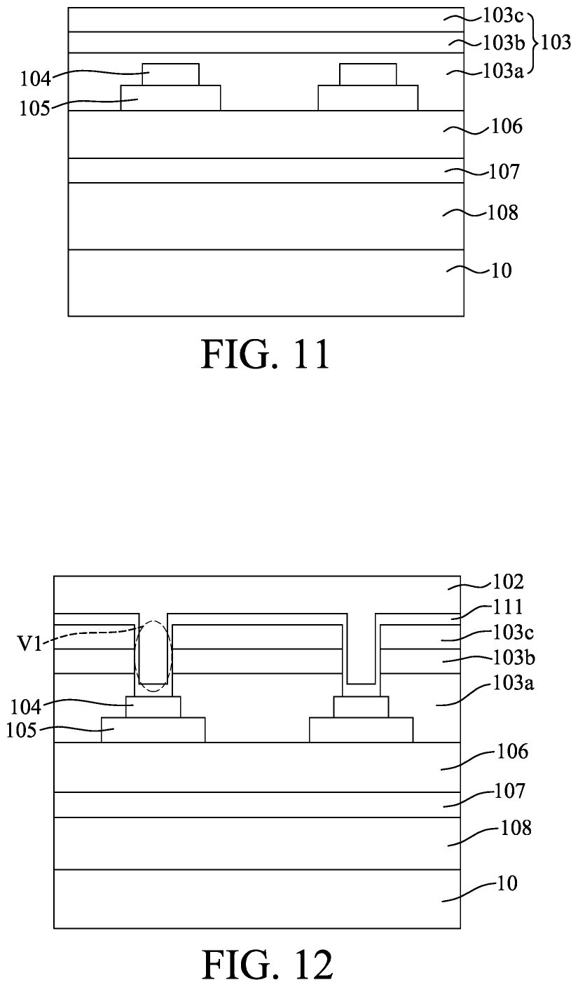

Referring to FIG. 11, the ohmic contact layer 104 is formed on the current spreading layer 105 by, e.g., physical or chemical deposition. By using a patterned photoresist and through photolithography and an etching procedure, the ohmic contact layer 104 is patterned. The current spreading layer 105 is then etched by a conventional etching process utilizing an inductively coupled plasma etching machine to form the recess regions and the non-recess regions. Thereafter, the light-transmissive dielectric layer 103 is formed on the recess regions and the non-recess regions of the current spreading layer 105 and the ohmic contact layer 104 by plasma-enhanced chemical vapor deposition (PECVD) or the like. The light-transmissive dielectric structure 103 includes the first sublayer 103a, the second sublayer 103b, and the third sublayer 103c sequentially disposed in the stacking direction. In this embodiment, the light-transmissive dielectric layer 103 is made of SiO₂/SiNₓ/SiO₂, and the ohmic contact layer 104 is made of ITO.

Referring to FIG. 12, by using a patterned photoresist and through photolithography and an etching procedure, a part of the light-transmissive dielectric structure 103 corresponding in position to the non-recess regions is removed to form the through holes (V1) which expose the ohmic contact layer 104. The adhesive layer 111 is then formed in the through holes (V1) and on the light-transmissive dielectric structure 103 away from the light-exiting surface. The reflection layer 102 is formed on the adhesive layer 111 away from the light-exiting surface.

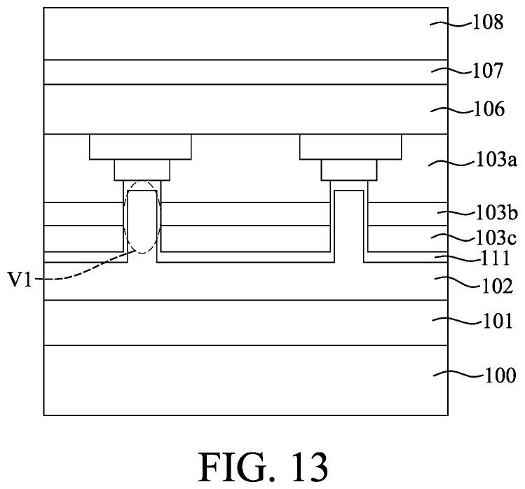

Next, the metal bonding layer 101 is disposed on the reflection layer 102 away from the light-transmissive dielectric layer 103, and bonds with the supporting substrate 100 via a bonding process. Then, the growth substrate 10 is removed by wet etching, so as to obtain a structure as shown in FIG. 13.

Finally, the first electrode 109 is formed on the first semiconductor layer 108, and the second electrode 110 is formed on the supporting substrate 100 away from the semiconductor epitaxial structure. The light-emitting device as shown in FIG. 6 is thus obtained.

In some embodiments, to further improve the luminous efficiency of the light emitted from the active layer 107 and exiting from the light-exiting surface, the roughened structure may be formed on the first semiconductor layer 108 away from the active layer 107 by etching so as to obtain the light-emitting device as shown in FIG. 9.

A brightness test was conducted on the light-emitting device (1A) of the embodiment of this disclosure that has the light-transmissive dielectric structure of SiO₂/SiNₓ/SiO₂ and on a light-emitting device (1B) of Comparative Example that has a single-layered light-transmissive dielectric structure of SiO₂. The result shows that the brightness of the light-emitting device 1A is greater than the brightness of the light-emitting device 1B by 5% to 10%.

According to the disclosure, a light-emitting apparatus according to this disclosure is also provided, and includes a packaging substrate and at least one of the aforesaid light-emitting devices disposed on the packaging substrate. A plant lighting apparatus according to the disclosure is also provided, and includes a circuit control board and a plant lighting device that includes at least one of the aforesaid light-emitting devices.

In summary, the light-transmissive dielectric structure 103 and the reflection layer 102 cooperatively form the total-reflection structure, the light-emitting device according to this disclosure exhibits improved light extraction efficiency and luminous brightness.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a semiconductor epitaxial structure that has a first surface and a second surface opposite to said first surface, and that includes a first semiconductor layer, an active layer, and a second semiconductor layer sequentially disposed in a stacking direction from said first surface to said second surface, said first surface being a light-exiting surface;
a reflection layer that is disposed on said semiconductor epitaxial structure away from said light-exiting surface, and that is adapted for reflecting light emitted by said active layer outwardly; and
a light-transmissive dielectric structure that is disposed between said reflection layer and said semiconductor epitaxial structure, said light-transmissive dielectric structure including a first sublayer made of a first material, a second sublayer made of a second material, and a third sublayer made of a third material that are sequentially disposed in the stacking direction, said first sublayer having a first refractive index (n₁), said second sublayer having a second refractive index (n₂), said third sublayer having a third refractive index (n₃), where n₂>n₁, n₂>n₃.

2. The light-emitting device as claimed in claim 1, wherein said second semiconductor layer has a refractive index (n₀), where n₀>n₁.

3. The light-emitting device as claimed in claim 1, wherein said second material is different from said first material and said third material, said first material is same as or different from said third material.

4. The light-emitting device as claimed in claim 1, wherein said first material of said first sublayer is MgF₂ or SiOₓ, said second material of said second sublayer is TiO₂ or SiNₓ, and said third material of said third sublayer is MgF₂ or SiOₓ.

5. The light-emitting device as claimed in claim 1, wherein a thickness of said first sublayer is kλ/4n₁, a thickness of said second sublayer is kλ/4n₂, and a thickness of said third sublayer is kλ/4n₃, A being a wavelength of the light emitted by said active layer, k being an odd number.

6. The light-emitting device as claimed in claim 1, further comprising an ohmic contact layer that is disposed between said semiconductor epitaxial structure and said reflection layer, said ohmic contact layer having a patterned structure.

7. The light-emitting device as claimed in claim 6, wherein said light-transmissive dielectric structure covers a part of a top surface of said ohmic contact layer away from said semiconductor epitaxial structure and a side surface of said ohmic contact layer.

8. The light-emitting device as claimed in claim 6, wherein said ohmic contact layer is a transparent conductive layer or a conductive metallic layer, said ohmic contact layer being made of ITO, IZO, gold-zinc, gold-germanium, nickel-gold, gold-germanium-nickel, gold-beryllium, or combinations thereof.

9. The light-emitting device as claimed in claim 6, wherein said light-transmissive dielectric structure has a through hole, said reflection layer filling said through hole and covering a top surface of said light-transmissive dielectric structure away from said semiconductor epitaxial structure.

10. The light-emitting device as claimed in claim 1, further comprising an ohmic contact layer, said light-transmissive dielectric structure having a plurality of through holes, said ohmic contact layer being disposed in at least one of said through holes of said light-transmissive dielectric structure.

11. The light-emitting device as claimed in claim 10, wherein said ohmic contact layer is a transparent conductive layer or a conductive metallic layer, said ohmic contact layer being made of ITO, IZO, gold-zinc, gold-germanium, nickel-gold, gold-germanium-nickel, gold-beryllium, or combinations thereof.

12. The light-emitting device as claimed in claim 1, further comprising an adhesive layer that is disposed between said light-transmissive dielectric structure and said reflection layer, said adhesive layer being made of IZO or ITO.

13. The light-emitting device as claimed in claim 12, wherein a thickness of said adhesive layer is no smaller than 2 nm.

14. The light-emitting device as claimed in claim 1, wherein said semiconductor epitaxial structure further includes a current spreading layer that is disposed on said second semiconductor layer away from said first surface, said current spreading layer having a recess region and a non-recess region, said light-transmissive dielectric structure being disposed on said recess region of said current spreading layer, said reflection layer being disposed on said non-recess region of said current spreading layer and on said light-transmissive dielectric structure away from said semiconductor epitaxial structure.

15. The light-emitting device as claimed in claim 14, further comprising an ohmic contact layer that is disposed between said reflection layer and said non-recess region of said current spreading layer, said ohmic contact layer having a patterned structure.

16. The light-emitting device as claimed in claim 15, wherein said light-transmissive dielectric structure covers a part of a top surface of said ohmic contact layer away from said semiconductor epitaxial structure and a side surface of said ohmic contact layer.

17. The light-emitting device as claimed in claim 14, wherein said light-transmissive dielectric structure has a plurality of through holes facing said non-recess region of said current spreading layer, said light-emitting device further including an ohmic contact layer disposed in at least one of said through holes of said light-transmissive dielectric structure.

18. The light-emitting device as claimed in claim 1, wherein said light-emitting device emits the light that has a wavelength ranging from 550 nm to 950 nm.

19. A light-emitting apparatus, comprising:
a packaging substrate; and
at least one light-emitting device according to claim 1 that is disposed on said packaging substrate.

20. A plant lighting apparatus, comprising:
a circuit control board; and
a plant lighting device that includes a light-emitting device as claimed in claim 1.
